(19) United States
(12) Patent Application Publication
(10) Pub. No.: US 2015/0357486 A1
(43) Pub. Date: Dec. 10, 2015

(54) SOLAR CELL INCLUDING MULTIPLE BUFFER LAYER FORMED BY ATOMIC LAYER DEPOSITION AND METHOD OF FABRICATING THE SAME

(71) Applicant: SK INNOVATION CO., LTD., Seoul (KR)

(72) Inventors: Keun LEE, Chungcheongbuk-do (KR); Won-Sub KWACK, Daejeon (KR); Jin-Hyock KIM, Daejeon (KR); Hye-Ri KIM, Chungcheongnam-do (KR); Jin-Woong KIM, Daejeon (KR)

(21) Appl. No.: 14/729,977

(22) Filed: Jun. 3, 2015

(30) Foreign Application Priority Data
Jun. 10, 2014 (KR) 10-2014-0069911

(51) Int. Cl. H01L 31/0216; H01L 31/0336; H01L 31/0224; H01L 31/18

(52) U.S. Cl. CPC H01L 31/02167; H01L 31/18; H01L 31/0336; H01L 31/022441

(57) ABSTRACT

Provided are a solar cell and a method for fabricating the same. The solar cell includes: a substrate; a back electrode layer formed on the substrate; a light absorbing layer formed on the back electrode layer; a buffer layer including an O-free first buffer layer formed on the light absorbing layer by atomic layer deposition (ALD) and a second buffer layer formed on the first buffer layer by the atomic layer deposition (ALD); and a front electrode layer formed on the buffer layer.

### CROSS-REFERENCE TO RELATED APPLICATIONS

The present application claims priority of Korean Patent Application No. 10-2014-0069911, filed on Jun. 10, 2014, which is incorporated herein by reference in its entirety.

### BACKGROUND OF THE INVENTION

1. Field of the Invention

The present invention relates to a solar cell including a multiple buffer layer formed by atomic layer deposition and a method of fabricating the same.

2. Description of the Related Art

As a renewable energy source capable of reducing carbon emission and complying with environmental regulations, a solar cell is highly relevant. The solar cell converts sunlight into electric energy. The solar cell is easy to install and easily generates power.

The solar cell is fabricated using single crystal silicon or polycrystalline silicon. Single crystal silicon generally has high photoelectric conversion efficiency and, as a result, has been prevalently used in large-scale power generation systems. However, single crystal silicon requires a complex fabrication process and is very expensive. Therefore, single crystal silicon is uneconomical.

Polycrystalline silicon has relatively lower efficiency but is inexpensive. Thus, a solar cell employing polycrystalline silicon is useful for a low-quality product, such as a residential power generation system. However, polycrystalline silicon also requires a complex fabrication process and thus there are limitations in lowering manufacturing costs to produce a solar cell. In addition, due to the rising price of raw material in recent years, it is still difficult to lower the production cost of a solar cell using the polycrystalline silicon.

As an alternative, in recent years a method using amorphous silicon having a multi-junction structure, and a method using a compound semiconductor having chalcogenide compounds which may be applied to a thin film type solar cell, have been developed.

### SUMMARY OF THE INVENTION

A solar cell according to an embodiment includes: a substrate; a back electrode layer formed over the substrate; a light absorbing layer formed over the back electrode layer; a buffer layer including a first buffer layer formed over the light absorbing layer and a second buffer layer formed over the first buffer layer; and a front electrode layer formed over the buffer layer, wherein the first buffer layer is an oxygen-free layer.

The first buffer layer includes ZnS, ZnSe, ZnTe, or a combination thereof. Band gap energy of the first buffer layer is 3.5 eV to 3.7 eV. A thickness of the first buffer layer is 0.2 nm to 2 nm. The second buffer layer includes a stack of an oxygen-containing atomic layer and an oxygen-free atomic layer. The oxygen-containing atomic layer includes (i) Zn and (ii) O. The oxygen-free atomic layer includes (i) Zn and (ii) S, Se, Te, or a combination thereof.

The second buffer layer includes a stack of a third buffer layer and a fourth buffer layer. The third buffer layer includes ZnO, ZnOS, ZnOSe, ZnOTe, or a combination thereof. The fourth buffer layer includes ZnS, ZnSe, ZnTe, or a combination thereof.

A thickness ratio of the third buffer layer and the fourth buffer layer is 3:1 to 10:1. A thickness of the second buffer layer is 4 nm to 50 nm.

The buffer layer includes 0.5 at % to 2 at % of Na when measured with respect to the total atoms included in the buffer layer. A content of Na included in the buffer layer is different depending on location and is the highest at an interface between the light absorbing layer and the buffer layer.

The substrate is a sodalime glass substrate. The sodalime glass substrate includes 13 at % to 15 at % of Na when measured with respect to the total atoms included in the sodalime glass substrate.

A method for fabricating a solar cell according to an embodiment includes: forming a back electrode layer over a substrate; forming a light absorbing layer over the back electrode layer; pre-treating a surface of the light absorbing layer with a reducing agent; forming a first buffer layer over the surface of the light absorbing layer by atomic layer deposition (ALD); forming a second buffer layer over the first buffer layer by atomic layer deposition (ALD); and forming a front electrode layer over the second buffer layer.

The first buffer layer is an oxygen-free layer. The pre-treating is performed by impregnating the surface of the light absorbing layer into H₂S, H₂Se, H₂Te, or a combination thereof. The first buffer layer includes ZnS, ZnSe, ZnTe, or a combination thereof.

The first buffer layer is formed by repeating a process cycle 1-10 times. The process cycle includes injecting a metal precursor gas, first purging, injecting a reaction gas, and second purging.

### BRIEF DESCRIPTION OF THE DRAWINGS

Embodiments will be more clearly understood from the following detailed description taken in conjunction with the accompanying drawings, in which:

FIG. 1 illustrates a schematic cross-sectional view of a solar cell according to an exemplary embodiment;

FIG. 2 is a flow chart illustrating a method for fabricating a solar cell according to an exemplary embodiment; and

FIGS. 3A to 3E are graphs illustrating measurement results of shunt resistance (R_shunt), series resistance (R_series), an open voltage Voc, a fill factor (FF), and relative efficiency of the a solar cell according to Examples 1 to 3 and Comparative Example 1, respectively.

### DETAILED DESCRIPTION

Hereinafter, exemplary embodiments will be described in detail with reference to the accompanying drawings. However, it is noted that the embodiments are exemplary and not limited to the embodiments described.

The same or like elements will be designated by the same reference numerals throughout the specification.

In the drawings, the thickness of layers and regions may be exaggerated for better understanding.

In the description below, forming a given component “on” a layer may indicate either the case when the given component is formed directly on the layer or the case when the given component is formed indirectly over the layer and having a third layer interposed therebetween.

Hereinafter, exemplary embodiments will be described in detail.

An exemplary embodiment provides a solar cell including: a substrate; a back electrode layer formed on the substrate; a light absorbing layer formed on the back electrode layer; a multiple buffer layer which includes an O-free first buffer layer formed on the light absorbing layer by atomic layer deposition (ALD) and a second buffer layer formed on the first buffer layer by the atomic layer deposition (ALD); and a front electrode layer formed on the multiple buffer layer.

Further, an exemplary embodiment of the present invention provides a method for fabricating a solar cell including: (a) forming a back electrode layer on a substrate; (b) forming a light absorbing layer on the back electrode layer; (c) pre-treating a surface of the light absorbing layer; (d) forming an O-free first buffer layer on the light absorbing layer of which the surface is pre-treated by atomic layer deposition and then forming a second buffer layer on the first buffer layer by the atomic deposition method (ALD); and (e) forming a front electrode layer on the second buffer layer.

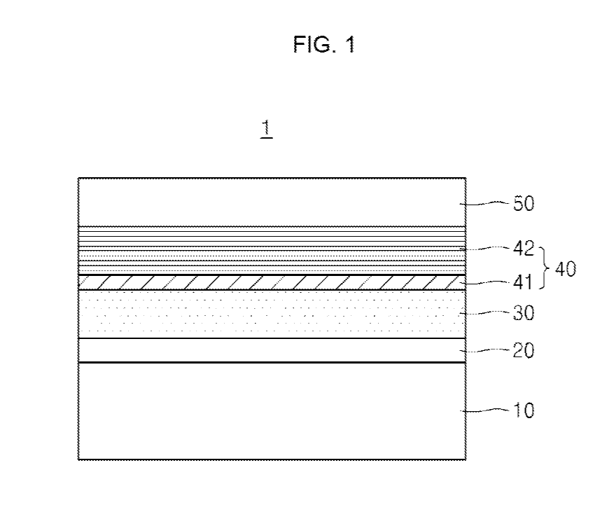

FIG. 1 is a schematic cross-sectional view of a solar cell according to an exemplary embodiment. The solar cell includes a multiple buffer layer formed by atomic layer deposition.

As illustrated in FIG. 1, the solar cell 1 including a multiple buffer layer formed by atomic layer deposition includes: a substrate 10; a back electrode layer 20 formed on the substrate 10; a light absorbing layer 30 formed on the back electrode layer 20; a multiple buffer layer 40 which includes a first buffer layer 41 and a second buffer layer 42; and a front electrode layer 50 formed on the multiple buffer layer 40. The first buffer layer 41 is formed on the light absorbing layer and formed by the atomic layer deposition (ALD). The first buffer layer 41 may be an oxygen-free layer. That is, substantially no oxygen is contained in the first buffer layer 41. Hereinafter, the first buffer layer 41 may be also referred to as an oxygen-free first buffer layer 41 or an O-free first buffer layer 41. The second buffer layer 42 is formed on the first buffer layer 41 and formed by the atomic layer deposition (ALD).

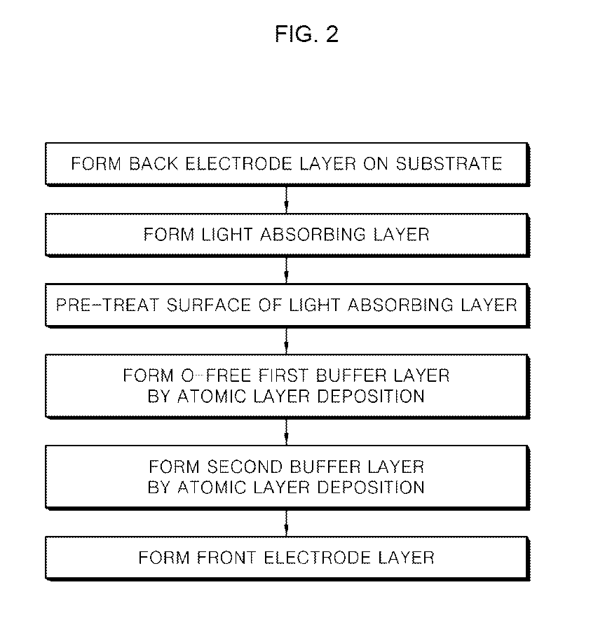

FIG. 2 is a flow chart illustrating a method for fabricating a solar cell according to an exemplary embodiment.

As illustrated in FIG. 2, a method for fabricating the solar cell 1 according to an exemplary embodiment includes: forming the back electrode layer 20 on the substrate 10; forming the light absorbing layer 30 on the back electrode layer 20; pre-treating a surface of the light absorbing layer 30; forming the first buffer layer 41 on the surface of the light absorbing layer 30 and forming the second buffer layer 42 on the first buffer layer 41 by the atomic deposition method (ALD); and forming the front electrode layer 50 on the second buffer layer 42.

### Substrate 10

As the substrate 10, a glass substrate may be used. However, the substrate 10 is not limited thereto. For example, a ceramic substrate, a metal substrate, a polymer substrate, or the like may also be used as the substrate 10. For example, as the glass substrate, a sodalime or high strained point soda glass substrate may be used. As the metal substrate, a substrate including stainless steel or titanium may be used. As the polymer substrate, a polyimide substrate may be used.

The substrate 10 may be transparent. The substrate 10 may be rigid or flexible.

According to the exemplary embodiment, after the light absorbing layer 30 is formed, the surface of the light absorbing layer 30 is pre-treated by impregnating into H₂S, H₂Se, H₂Te, or a combination thereof. Then, the oxygen-free first buffer layer is formed by the atomic layer deposition. The first and the second buffer layers prevent Na contained in the substrate 10 from diffusing.

As a result, even when the sodalime glass substrate is employed, it is possible to effectively prevent alkali compound such as Na from diffusing. In an embodiment, the sodalime glass substrate may include 70 to 73 wt % of SiO₂, 1 to 2 wt % of Al₂O₃, 12 to 13 wt % of CaO/MnO, 13 to 15 wt % of Na₂O/K₂O, etc. The content of Na included in the sodalime glass substrate may range from 13 at % to 15 at % with respect to the total atoms included in the sodalime glass substrate.

### Back Electrode Layer 20

The back electrode layer 20 is formed on the substrate 10 and may include metal such as Mo. The back electrode layer 20 may be a conductive layer.

The back electrode layer 20 may be formed of a single layer or multiple layers. When the back electrode layer 20 is formed of multiple layers, each layer may be made of the same metal as each other or different metals from each other.

The back electrode layer 20 may be formed by sputtering, vacuum evaporation, chemical vapor deposition, atomic layer deposition, ion beam deposition, screen printing, spray deep coating, tape casting, and inkjet.

A thickness of the back electrode layer 20 may preferably range from 0.1 μm to 1 μm, more preferably, 0.5 μm, but is not limited thereto.

### Light Absorbing Layer 30

The light absorbing layer 30 is formed on the back electrode layer 20 and is formed by deposition. The light absorbing layer 30 is subject to heat treatment.

The light absorbing layer may preferably include chalcogenide compounds. For example, CuInS₂(CIS), CuGaS₂(CGS), CuInSe₂(CISe), CuGaSe₂(CGSe), CuAlSe₂(CASe), CuInTe₂(CITe), CuGaTe₂(CGTe), Cu(In, Ga)S₂(CIGS), Cu(In, Ga)Se₂(CIGSe), Cu₂ZnSnS₄(CZTS), CdTe, and a combination thereof may be used. However, the light absorbing layer is not limited thereto.

The deposition of the light absorbing layer may be made by vacuum deposition or a non-vacuum deposition. In detail, deposition of the light absorbing layer may include sputtering, vacuum evaporation, chemical vapor deposition, atomic layer deposition, ion beam deposition, or a combination thereof. Non-vacuum deposition of the light absorbing layer maybe made by screen printing, spray deep coating, tape casting, inkjet, or a combination thereof.

The heat treatment may be performed simultaneously with the deposition of the material of the light absorbing layer. In another embodiment, the heat treatment may be performed after the deposition of the material of the light absorbing layer.

The heat treatment may be performed under Se atmosphere or S atmosphere and may be performed at 300° C. to 600° C. for 30 minutes to one hour.

For example, Cu, In, Ga, and Se precursors are deposited by sputtering. Then, heat treatment using H₂Se or H₂S gas is performed in a heat treatment chamber to form Cu(In, Ga)S₂(CIGS) or Cu(In, Ga)Se₂(CIGSe) chalcogenide compound. Specifically, Cu, In, Ga, and Se precursors in a solid form are placed in a furnace and the furnace is heated to provide a high vacuum atmosphere. The Cu, In, Ga, and Se precursors are evaporated under the high vacuum atmosphere, thereby forming the light absorbing layer 30 including the Cu(In, Ga)S₂(CIGS) chalcogenide compound.

### Buffer Layer 40

The buffer layer 40 is formed on the light absorbing layer 30 and includes the oxygen-free first buffer layer 41 and the second buffer layer 42.

The oxygen-free first buffer layer 41 is formed on the light absorbing layer 30 by the atomic layer deposition (ALD). The second buffer layer 42 is formed on the first buffer layer 41 by the atomic layer deposition (ALD).

The oxygen-free first buffer layer 41 includes substantially no oxygen. That is, the oxygen content in the first buffer layer 41 is about 0 at %.

In an embodiment, the buffer layer 40 is an n-type semiconductor layer and the light absorbing layer 30 is a p-type semiconductor layer. Therefore, the light absorbing layer 30 and the buffer layer 40 form a pn junction. The light absorbing layer 30 and the front electrode layer 50 have a large difference in a lattice constant and in an energy band gap. The buffer layer 40 has a band gap between the light absorbing layer 30 and the front electrode layer 50. Thus, when the buffer layer 40 is provided between the light absorbing layer 30 and the front electrode layer 50, the junction characteristics between the light absorbing layer 30 and the front electrode layer 50 may improve.

CdS is not proper for the buffer layer 40 because CdS formed by chemical bath deposition (CBD) causes pollution and an environmental issue. In an embodiment, the buffer layer may include ZnO, a composite of Zn, O, and S (hereinafter, also referred to as Zn(O, S)), a composite of Zn, O, and Se (also referred to as Zn(O, Se)), a composite of Zn, O, and Te (also referred to as Zn(O, Te)), and the like. The buffer layer may be formed by the atomic layer deposition (ALD). A large amount of alkali compounds such as Na—O and Na—Se—O are formed on the surface of the light absorbing layer due to oxidizing agents H₂O, H₂O₂, and O₃ which are used in the atomic layer deposition (ALD), thus reducing performance of the solar cell.

To address this issue, in an embodiment, the surface of the light absorbing layer 30 is pre-treated prior to forming the second buffer layer 42 and the oxygen-free first buffer layer 41.

In other words, the buffer layer 40 includes the oxygen-free first buffer layer 41 which is formed on the pre-treated light absorbing layer 30 by the atomic layer deposition (ALD) and the second buffer layer 42 which is formed on the first buffer layer 41 by the atomic layer deposition (ALD).

First, the surface pre-treatment may be performed by impregnating the surface of the light absorbing layer 30 in a reducing agent (or a deoxidizing agent) such as H₂S, H₂Se, H₂Te, or a combination thereof. The impregnation may make a thickness and a composition of the surface of the light absorbing layer 30 uniform and greatly increase the number of active sites on the surface of the light absorbing layer 30. Thus, the buffer layer 40 may be easily formed by the atomic layer deposition.

For example, the impregnation may be performed in a chamber having a volume of 300×300×15 mm³ to 700×1000×700 mm³. The flow condition of the impregnation may be changed depending on a size of the chamber. For example, the impregnation is preferably performed under the flow condition of 100 sccm to 10000 sccm, but the flow condition is not limited thereto. When the flow condition is less than the range, the light absorbing layer 30 may not be sufficiently impregnated in H₂S, etc. As a result, composition uniformity and thickness uniformity of the buffer layer 40 may deteriorate.

In contrast, when the flow condition exceeds the range, the uniformity of the buffer layer 40 may deteriorate as well due to a turbulent flow in the chamber. In addition, a process time may increase to purge non-reacted gas. Characteristics of the light absorbing layer 30 may deteriorate when the process time increases.

Further, the time condition of the impregnation may be changed depending on the size of the chamber and the flow condition of injecting gas. The impregnation is preferably performed for 30 seconds to 5 minutes but is not limited thereto. When the time duration of impregnation is less than 30 seconds, the light absorbing layer 30 is not sufficiently impregnated in H₂S, etc. Therefore, composition ratio uniformity and thickness uniformity of the buffer layer 40 may deteriorate.

In contrast, when the impregnation is performed exceeding 5 minutes, the process time may increase to purge non-reacted gas from the chamber. Characteristics of the light absorbing layer 30 may deteriorate when the process time increases.

The first buffer layer 41 is oxygen-free and is formed on the light absorbing layer 30 by the atomic layer deposition (ALD). That is, the first buffer layer 41 does not substantially include oxygen. The first buffer layer 41 may include ZnS, ZnSe, ZnTe, or a combination thereof.

The first buffer layer 41 may prevent the oxidizing agents such as H₂O, H₂O₂, and O₃ from being created during the subsequent atomic layer deposition (ALD) and prevent the performance of the solar cell 1 from deteriorating due to alkali compounds such as Na—O and Na—Se—O which are formed on the surface of the light absorbing layer 30 in large quantities during the subsequent atomic layer deposition (ALD).

When the first buffer layer 41 has high band gap energy, for example, from 3.5 eV to 3.7 eV, there is a need to optimize the thickness of the first buffer layer 41 to control a conduction band offset between the light absorbing layer 30 and the first buffer layer 41.

The atomic layer deposition (ALD) of the first buffer layer 41 may be performed by repeating a process cycle which includes injecting metal precursor gas, first purging, injecting reaction gas, and second purging. The metal precursor gas may be diethyl zinc (DEZ) and the reaction gas may be H₂S, H₂Se, H₂Te, or a combination thereof.

The process cycle is preferably repeated one to ten times, more preferably twice to six times but is not limited thereto. When the process cycle is less than the number of times, the function of the buffer layer 41 may not be performed properly. When the process cycle exceeds the number of times, the thickness of the first buffer layer 41 is too thick and therefore the conduction band offset may not be controlled.

The thickness of the first buffer layer preferably ranges from 0.2 nm to 2 nm, more preferably 0.4 nm to 1.2 nm but is not limited thereto. In this case, when the thickness of the first buffer layer 41 is less than the range, the material of the O-free first buffer layer 41 does not sufficiently coat the whole surface of the light absorbing layer 30. Therefore the alkali compounds like Na—O, Na—Se—O, etc., may be formed on the surface of the light absorbing layer 30 in the subsequent process depositing the second buffer layer 42. When the thickness of the first buffer layer 41 exceeds the range, the first buffer layer 41 becomes too thick. Therefore, the conduction band offset between the light absorbing layer and the buffer layer is increased and an open voltage Voc is reduced accordingly, thereby reducing performance of the solar cell 1.

The second buffer layer 42 is formed on the first buffer layer 41 by the atomic layer deposition (ALD). The second buffer layer 42 may be a nano-mixed layer. For example, the nano-mixed layer may be formed by alternately stacking atomic layers of Zn, O, and a composite of Zn and any of S, Se, Te, and a combination thereof (hereinafter, also referred to as a composite of Zn(S, Se, Te)).

In another embodiment, the second buffer layer 42 is a nano-laminated layer. For example, the second buffer layer 42 may include a third buffer layer and a fourth buffer layer. The third buffer layer may include ZnO, Zn—O—S, Zn—O—Se, Zn—O—Te, or a combination thereof. The fourth buffer layer may include ZnS, ZnSe, and ZnTe. The third and the fourth buffer layers are alternately stacked.

When the second buffer layer 42 is the nano-mixed layer, it is difficult to distinguish the respective layers from each other. However, when the second buffer layer 42 is the nano-laminated layer, it is possible to distinguish the third buffer layer from the fourth buffer layer.

Compared with the nano-mixed layer, the nano-laminated layer is more preferable in that process controllability of the conduction band offset is diverse.

The band gap energy is changed depending on a relative content of O and S. In case of the nano-mixed layer, the atomic layers of ZnO and ZnS are alternately stacked, and the conduction band offset between the light absorbing layer and the buffer layer may be controlled merely by controlling the process cycle ratio.

On the other hand, in the case of the nano-laminated layer in which the third buffer layer including ZnO and the fourth buffer layer including ZnS are alternately stacked, the conduction band offset between the light absorbing layer and the buffer layer may be controlled by a combination of (i) controlling the process cycle ratio (or the thickness ratio of the third buffer layer and the fourth buffer layer) and (ii) controlling the number of the third or the fourth buffer layer included in the second buffer layer. As a result, more complicated and relatively fine control may be made.

In detail, in the second buffer layer 42 formed of the nano-laminated layer, the third buffer layer may include ZnO, a composite of Zn—O—S, a composite of Zn—O—Se, a composite of Zn—O—Te, or a combination thereof. That is, the third buffer layer which is formed on the first buffer layer 41 may prevent the alkali compounds such as Na—O and Na—Se—O from being formed on the surface of the light absorbing layer 30, thereby preventing performance of the solar cell 1 from deteriorating. Due to the presence of the third buffer layer including O or the first buffer layer 41, even though the oxidizing agents H₂O, H₂O₂, and O₃ are used in the atomic layer deposition (ALD), the alkali compounds is not formed on the surface of the light absorbing layer 30. The atomic layer deposition (ALD) for forming the third buffer layer may repeat the process cycle of injecting metal precursor gas, first purging, injecting reaction gas, and second purging. The metal precursor gas may be diethyl zinc (DEZ) and the reaction gas may be H₂O, H₂S, H₂Se, H₂Te, or a combination thereof.

When the second buffer layer 42 is formed of the nano-laminated layer, the fourth buffer layer may include ZnS, ZnSe, ZnTe, or a combination thereof. That is, like the first buffer layer, the fourth buffer layer is an oxygen-free layer. The atomic layer deposition (ALD) for forming the fourth buffer layer may repeat the process cycle of injecting metal precursor gas, first purging, injecting the reaction gas, and second purging. The metal precursor gas may be the diethyl zinc (DEZ) and the reaction gas may be H₂S, H₂Se, H₂Te, or a combination thereof.

The process cycle ratio of the third buffer layer and the fourth buffer layer preferably ranges from 3:1 to 10:1 but is not limited thereto. When the process cycle ratio of the third buffer layer and the fourth buffer layer is less than 3:1, the conduction band offset between the light absorbing layer and the buffer layer is increased and therefore a short current Jsc may be reduced. When the process cycle ratio of the third buffer layer and the fourth buffer layer exceeds 10:1, the conduction band offset between the light absorbing layer and the buffer layer is reduced and therefore the open voltage Voc may be reduced.

In detail, when the process cycle ratio of the third buffer layer and the fourth buffer layer is less than 3:1, the alternate frequency may be 5-63 times. When the process cycle ratio of the third buffer layer and the fourth buffer layer is 10:1, the alternate frequency may be 1-13 times. Repetition of the process cycle for 5-63 times may result in the buffer layer 40 to the thickness of 4 nm to 50 nm. The thickness ratio of the third buffer layer and the fourth buffer layer preferably ranges from 3:1 to 10:1 but is not limited thereto. When the thickness ratio of the third buffer layer and the fourth buffer layer is less than 3:1, the conduction band offset between the light absorbing layer and the buffer layer is increased and therefore a short current Jsc may be reduced. When the thickness ratio of the third buffer layer and the fourth buffer layer exceeds 10:1, the conduction band offset between the light absorbing layer and the buffer layer is reduced and therefore the open voltage Voc may be reduced.

Further, each of the atomic weight ratio of O:S, O:S, and O:Te in the second buffer layer 42 preferably ranges from 19:6 to 9:1 but is not limited thereto. Each of the molar ratio of O:S, O:S, and O:Te in the second buffer layer 42 may be 19:6 to 9:1, as well. Therefore, the conduction band offset between the light absorbing layer and the buffer layer may be formed and controlled within a range of 0.0 eV to 0.4 eV such that the optimal conditions of the open voltage Voc and the short current Jsc may be obtained.

The thickness of the second buffer layer 42 preferably ranges from 4 nm to 50 nm but is not limited thereto. When the thickness of the second buffer layer 42 is less than 4 nm, thickness uniformity of the second buffer layer 42, which is formed on the light absorbing layer 30 having very large surface roughness of tens of nm to hundreds of nm, deteriorates and therefore the open voltage Voc may be reduced, thereby reducing the efficiency of the solar cell. When the thickness of the second buffer layer 42 exceeds 50 nm, transmittance is reduced and the amount of light incident into the light absorbing layer 30 is reduced. Therefore, the short current Jsc may be reduced, thereby reducing the efficiency of the solar cell 1.

As the result of forming the O-free first buffer layer by the atomic layer deposition, the buffer layer 40 has a small content of Na. For example, the content of Na of the buffer layer 40 ranges from 0.5 at % to 2 at %, but is not limited thereto.

Further, to reduce the content of Na in the buffer layer 40, the light absorbing layer 30 may be subject to surface heat treatment. The surface heat treatment may be performed under the gas atmosphere of air, NN₂, Ar, O₂, H₂O, H₂O₂, or a combination thereof. For example, the surface heat treatment may be performed at a temperature of 100° C. to 250° C. for 1 minute to 30 minutes.

Further, after the light absorbing layer is subject to the surface heat treatment, the light absorbing layer may be cleaned by a cleaning solution NH₄OH, HNO₃, HCl, H₂SO₄, NH₄F, HF, H₂O₂, CdSO₄, KCN, DI-water, or a combination thereof. In another embodiment, the light absorbing layer may be cleaned using a cleaning gas and plasma. For example, the cleaning gas may include NH₃, ClF₃, F₂, H₂O, O₂, N₂O, NF₃, N₂, and a combination thereof. The plasma may be created using a reaction gas such as Ar, N₂, O₂, H₂O, H₂, He, CH₄, NH₃, CF₄, C₂H₂, C₃H₈, and a combination thereof. The cleaning condition may be set to a temperature of 100° C. to 120° C. for 30 seconds to 5 minutes, for example.

The content of Na in the buffer layer 40 may be different depending on location. For example, the content of Na may be highest at an interface between the light absorbing layer 30 and the buffer layer 40. Relatively a larger amount of Na is present on the surface of the light absorbing layer 30 than the inside of the light absorbing layer 30. Na is combined with O to form alkali compounds such as Na—O and Na—Se—O. Thus, in a conventional solar cell, the alkali compounds are present in a high concentration at the interface between the light absorbing layer 30 and the buffer layer 40.

In an embodiment, the O-free first buffer layer formed by the atomic layer deposition may include an impurity such as C, H, OH, and a combination thereof about 3 wt %, but is not limited thereto. When the content of the impurity present in the buffer layer 40 is in excess of 3 wt %, a conductive path is formed between the light absorbing layer 30 and the front electrode layer 50, and thus shunt resistance (R-shunt) may be reduced. The content of the impurity may be checked by XRD, AES, SIMS, etc.

### Front Electrode Layer 50

The front electrode layer 50 is formed on the buffer layer 40. The front electrode layer 50 forms a pn junction with the light absorbing layer 30 and may be made of ZnO, aluminum (Al), ZnO doped with alumina (Al₂O₃), ITO, etc.

The front electrode layer 50 may be formed in a double structure in which an n-type ZnO thin film or an indium tin oxide (ITO) thin film having excellent electro-optic characteristics is deposited on an i-type ZnO thin film.

The i-type ZnO thin film serves as a transparent electrode of a front surface of the solar cell. The front electrode layer 50 may be formed of an undoped ZnO thin film having high light transmittance and good electrical conductivity. The n-type ZnO thin film or the indium tin oxide which is deposited on the i-type ZnO thin film has a low resistance value.

In the solar cell 1 including the buffer layer according to an embodiment of the present invention, the surface of the light absorbing layer 30 is impregnated into H₂S, H₂Se, H₂Te, or a combination thereof prior to forming the buffer layer 40. The O-free first buffer layer 41 formed by the atomic layer deposition prevents diffusion of the alkali compounds, thereby reducing the shunt resistance (R-shunt) and increasing a fill factor (FF).

The solar cell 1 including the buffer layer 40 according to an embodiment of the present invention may be fabricated in a large size, for example, 4 square inches or larger.

Hereinafter, preferred examples will be described. However, the following examples are only provided to help understand the present invention and the present invention is not limited to the following examples.

### Example 1

The back electrode layer having a thickness of 0.5 μm was formed by coating Mo-based alloys on the sodalime glass substrate by DC sputtering. The Cu, In, Ga, and Se precursors were deposited on the back electrode layer by the DC sputtering. Then, the back electrode layer was heat-treated at 550° C. for 30 to 60 minutes under Se atmosphere to form the light absorbing layer including CIGS-based compounds and having a thickness of 2 μm. The surface of the light absorbing layer was placed in a chamber. H₂S is supplied to the chamber at a flow rate of 100 to 5000 sccm for 2 minutes. The chamber has a volume of 300×300×15 mm³ to 700×1000×700 mm³.

Next, a ZnS layer was formed to a thickness of 0.8 nm on the light absorbing layer by the atomic layer deposition (ALD). The ZnS layer serves as the first buffer layer. For the atomic layer deposition of the first buffer layer, the process cycle of injecting diethyl zinc (DEZ) metal precursor gas for 1 to 2 seconds, purging for 2 to 8 seconds, injecting H₂S reaction gas for 0.5 to 2 seconds, and purging for 2 to 8 seconds are repeated four times.

Next, a ZnO buffer layer to a thickness of 1.0 nm was formed on the first buffer layer by the atomic layer deposition (ALD). The ZnO buffer layer serves the third buffer layer. A ZnS buffer layer to a thickness of 0.2 nm was formed on the ZnO buffer layer by the atomic layer deposition (ALD). The ZnS buffer layer serves as the fourth buffer layer. The ZnO buffer layer and the ZnS buffer layer are formed repeatedly 33 times in an alternate manner to form the second buffer layer to a thickness of 40 nm. The atomic layer deposition of the third buffer layer was formed by repeating five times the process cycle of injecting the diethyl zinc (DEZ) metal precursor gas for 1 to 2 seconds, purging for 2 to 8 seconds, injecting the H₂O reaction gas for 1 to 2 seconds, and purging for 2 to 8 seconds. The atomic layer deposition of the fourth buffer layer was formed by performing the process cycle once of injecting the diethyl zinc (DEZ) metal precursor gas for 1 to 2 seconds, purging for 2 to 8 seconds, injecting the H₂S reaction gas for 0.5 to 2 seconds, and purging for 2 to 8 seconds.

Next, the i-type ZnO thin film having a thickness of 50 nm and the n-type ZnO thin film having a thickness of 1000 nm was formed by a RF sputtering method to form the front electrode layer. As such, the solar cell was obtained.

### Example 2

Example 2 was performed in the same manner as the above Example 1, except that the process cycle to form the first buffer layer is repeated twice, rather than four times.

### Example 3

Example 3 was performed in the same manner as the above Example 1, except that the process cycle for the first buffer layer is repeated sixth times, rather than four times.

### Comparative Example 1

Comparative Example 1 was performed in the same manner as the Example 1, except that the surface of the light absorbing layer is not treated with the H₂S and the first buffer layer is not formed.

### Evaluation (1) Evaluation of Performance for Each Factor of Solar Cell

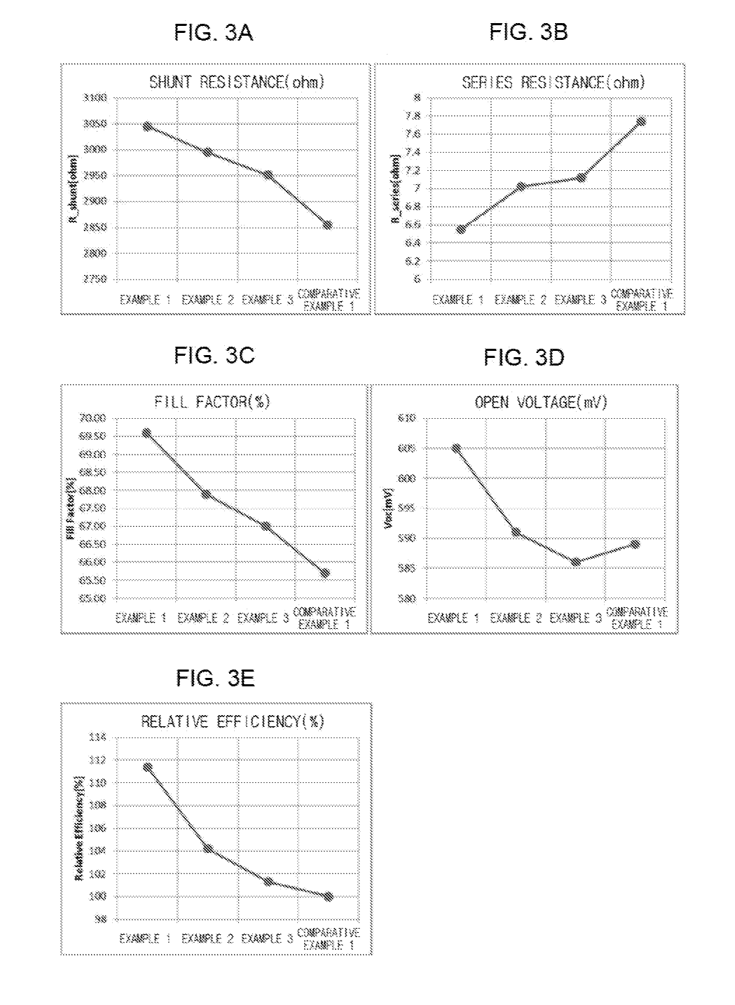

The solar cells fabricated according to the above Examples 1 to 3 and the above Comparative Example 1 were evaluated. The results were shown in Table 1 and FIG. 3.

TABLE 1

| | Shunt | Series | Open | | Relative |
|---|---|---|---|---|---|
| | resistance | resistance | voltage | Fill factor | Efficiency |
| | (ohm) | (ohm) | (mV) | (%) | (%) |
| Example 1 | 3045 | 6.55 | 605 | 69.6 | 111.4 |
| Example 2 | 2995 | 7.02 | 591 | 67.9 | 104.2 |
| Example 3 | 2951 | 7.12 | 586 | 67.0 | 101.3 |
| Comparative | 2855 | 7.74 | 589 | 65.7 | 100.0 |
| Example 1 | | | | | |

As can be appreciated from the above Table 1 and FIG. 3, compared with the above Comparative Example 1, Examples 1 to 3 showed higher shunt resistance (R_shunt), lower series resistance (R_series), and a higher fill factor (FF). Further, Examples 1 to 3 showed an open voltage (Voc) higher than or equivalent to the Comparative Example 1. Therefore, compared with the above Comparative Example 1, Examples 1 to 3 showed improved efficiency than the Comparative Example 1 by 1.3 to 11.4%. Such improvement may be attributed to treatment of the surface of the light absorbing layer with H₂S and presence of the ZnS first buffer layer, thereby preventing diffusion of the alkali compounds Na—O and Na—Se—O.

According to embodiments of the present invention, the solar cell includes the multiple buffer layer which includes the O-free first buffer layer formed on the light absorbing layer by the atomic layer deposition (ALD) and the second buffer layer formed on the first buffer layer by the atomic layer deposition (ALD), thereby preventing diffusion of the alkali compound and enhancing performance of the solar cell.

Further, according to embodiment of the present invention, the solar cell may be fabricated in a large size, for example, 4 square inches or larger.

The foregoing description of the present invention is only an example and those skilled in the art will appreciate that the present invention may be easily changed to other detailed forms, without departing from technical ideas or essential features of the present invention scope and spirit of the invention. Therefore, it should be understood that the above-mentioned embodiments are not restrictive but are exemplary in all aspects.

What is claimed is:

1. A solar cell, comprising:
a substrate;
a back electrode layer formed over the substrate;
a light absorbing layer formed over the back electrode layer;
a buffer layer including a first buffer layer formed over the light absorbing layer and a second buffer layer formed over the first buffer layer; and
a front electrode layer formed over the buffer layer,
wherein the first buffer layer is an oxygen-free layer.

2. The solar cell of claim 1, wherein the first buffer layer includes ZnS, ZnSe, ZnTe, or a combination thereof.

3. The solar cell of claim 1, wherein band gap energy of the first buffer layer is 3.5 eV to 3.7 eV.

4. The solar cell of claim 1, wherein a thickness of the first buffer layer is 0.2 nm to 2 nm.

5. The solar cell of claim 1,
wherein the second buffer layer includes a stack of an oxygen-containing atomic layer and an oxygen-free atomic layer,
wherein the oxygen-containing atomic layer includes (i) Zn and (ii) O, and
wherein the oxygen-free atomic layer includes (i) Zn and (ii) S, Se, Te, or a combination thereof.

6. The solar cell of claim 1,
wherein the second buffer layer includes a stack of a third buffer layer and a fourth buffer layer,
wherein the third buffer layer includes ZnO, ZnOS, ZnOSe, ZnOTe, or a combination thereof, and
wherein the fourth buffer layer includes ZnS, ZnSe, ZnTe, or a combination thereof.

7. The solar cell of claim 6, wherein a thickness ratio of the third buffer layer and the fourth buffer layer is 3:1 to 10:1.

8. The solar cell of claim 1, wherein a thickness of the second buffer layer is 4 nm to 50 nm.

9. The solar cell of claim 1, wherein the buffer layer includes 0.5 at % to 2 at % of Na when measured with respect to the total atoms included in the buffer layer.

10. The solar cell of claim 1, wherein a content of Na included in the buffer layer is different depending on location and is the highest at an interface between the light absorbing layer and the buffer layer.

11. The solar cell of claim 1, wherein the substrate is a sodalime glass substrate.

12. The solar cell of claim 11, wherein the sodalime glass substrate includes 13 at % to 15 at % of Na when measured with respect to the total atoms included in the sodalime glass substrate.

13. A method for fabricating a solar cell, comprising:
forming a back electrode layer over a substrate;
forming a light absorbing layer over the back electrode layer;
pre-treating a surface of the light absorbing layer with a reducing agent;
forming a first buffer layer over the surface of the light absorbing layer by atomic layer deposition (ALD);
forming a second buffer layer over the first buffer layer by atomic layer deposition (ALD); and
forming a front electrode layer over the second buffer layer,
wherein the first buffer layer is an oxygen-free layer.

14. The method of claim 13, wherein the pre-treating is performed by impregnating the surface of the light absorbing layer into H₂S, H₂Se, H₂Te, or a combination thereof.

15. The method of claim 13, wherein the first buffer layer includes ZnS, ZnSe, ZnTe, or a combination thereof.

16. The method of claim 13, wherein the first buffer layer is formed by repeating a process cycle 1-10 times,
wherein the process cycle includes injecting a metal precursor gas, first purging, injecting a reaction gas, and second purging.
